(19) United States
(12) Patent Application Publication
(10) Pub. No.: US 2008/0225918 A1
(43) Pub. Date: Sep. 18, 2008

(54) INDEX GUIDED SEMICONDUCTOR LASER WITH LOSS-COUPLED GRATINGS AND CONTINUOUS WAVEGUIDE

(76) Inventors: Martin Achtenhagen, Plano, TX (US); Gary Alan Evans, Plano, TX (US); Nuditha Vibhavie Amarasinghe, Richardson, TX (US); Taha Masood, Plano, TX (US); Jerome K. Butler, Richardson, TX (US)

Correspondence Address: SLATER & MATSIL, L.L.P., 17950 PRESTON RD, SUITE 1000, DALLAS, TX, 75252-5793, US

(21) Appl. No.: 11/686,082

(22) Filed: Mar. 14, 2007

(51) Int. Cl. H01S 5/026

(52) U.S. Cl. 372/44.01; 438/29

(57) ABSTRACT

A system and a method of manufacture for a semiconductor laser with a continuous waveguide ridge extending the length of the laser. The continuous waveguide ridge is positioned through the center of the optical components of the semiconductor laser. The optical components including the waveguide ridge may be distributed Bragg reflectors (DBRs), outcoupling gratings, and phase controllers. The illustrated embodiments include lateral-grating grating-stabilized edge-emitting lasers and lateral-grating grating-stabilized surface-emitting (GSE) lasers. Both loss-coupled and non-loss-coupled lateral-grating components are illustrated.

### BACKGROUND OF THE INVENTION

1. Technical Field

The illustrative embodiments relate generally to semiconductor lasers. Still more particularly, the illustrative embodiments relate to a system and a method of manufacture for a semiconductor laser incorporating a continuous waveguide ridge using loss-coupled lateral-gratings for feedback and/or outcoupling.

2. Description of Related Art

A laser is an optical source that emits photons in a coherent beam. Laser light is typically a single wavelength or color, and emitted in a narrow beam. Laser action is explained by the theories of quantum mechanics and thermodynamics. Many materials have been found to have the required characteristics to form the laser gain medium needed to power a laser, and these have led to the invention of many types of lasers with different characteristics suitable for different applications.

A semiconductor laser is a laser in which the active medium is a semiconductor. A common type of semiconductor laser is formed from a p-n junction, a region where p-type and n-type semiconductors meet, and powered by injected electrical current. As in other lasers, the gain region of the semiconductor laser is surrounded by an optical cavity. An optical cavity is an arrangement of mirrors, or reflectors that form a standing wave cavity resonator for light waves. Optical cavities surround the gain region and provide feedback of the laser light. In a simple form of semiconductor laser, for example a laser diode, an optical waveguide may be formed in epitaxial layers, such that the light is confined to a relatively narrow area perpendicular (and parallel) to the direction of light propagation.

Many typical semiconductor lasers are edge-emitting lasers, which are also called in-plane lasers. In edge-emitting lasers, the laser light propagates parallel to the wafer surface of the semiconductor chip and is partially reflected and coupled out at a cleaved edge.

A grating-outcoupled surface-emitting (GSE) laser is typically formed with an outcoupling grating between (or outside) two separate distributed Bragg reflectors (DBRs). A grating-outcoupled surface-emitting laser has a gain region comprised of a lateral waveguide, which may be a waveguide ridge, and an electrical contact for injecting electrical current to pump the active gain region located between the gratings. The outcoupling grating couples light out of the GSE laser, often normal or near-normal to the surface. Distributed Bragg reflectors are located outside the waveguide ridge gain regions in a GSE laser. The outcoupling grating may be placed between the distributed Bragg reflectors or outside the distributed Bragg reflectors.

A distributed Bragg reflector is a structure formed from multiple layers of alternating materials with a varying refractive index, or by periodic variation of some characteristic, such as height of a material, resulting in periodic variation in the effective refractive index in the material. Each boundary of variation causes a partial reflection of an optical wave. These variations in height look visually like a series of parallel lines and are referred to herein as grating lines. When the many reflections combine by constructive interference, high reflectivity over a narrow wavelength range is achieved. Typically, distributed Bragg reflectors are passive structures positioned at either end of, and separate from, the waveguide ridge gain region. The waveguide ridge is a structure that aids in containing the light in the laser.

Outcoupling gratings are structures typically similar to distributed Bragg reflectors in form; however, the period of the variation in refractive index or height is larger. The variation in height in an outcoupler also appears visually as a series of parallel lines, and is referred to as an outcoupler grating. The grating lines are depicted on the following figures as alternately shaded areas.

### SUMMARY OF THE INVENTION

The illustrated embodiments provide an apparatus, a system, and a method of manufacture for a semiconductor laser with a continuous waveguide ridge extending the length of the laser. The continuous waveguide ridge is positioned through the center of the optical components of the semiconductor laser. The optical components, including the waveguide ridge, may be distributed Bragg reflectors (DBRs), gain sections, outcoupling gratings and phase controllers. The illustrated embodiments include lateral-grating grating-stabilized edge-emitting lasers and lateral-grating grating-stabilized surface-emitting (GSE) lasers. Both loss-coupled and non-loss-coupled lateral-grating components are illustrated.

### BRIEF DESCRIPTION OF THE DRAWINGS

The novel features believed characteristic of the invention are set forth in the appended claims. The invention itself, however, as well as a preferred mode of use, further objectives and advantages thereof, will best be understood by reference to the following detailed description of an illustrative embodiment when read in conjunction with the accompanying drawings, wherein:

FIG. 1 is a top view of a known grating-outcoupled surface-emitting laser;

FIG. 2 depicts a lengthwise cross-sectional view of the known grating-outcoupled surface-emitting laser of FIG. 1;

FIG. 3 is a top view of a continuous waveguide ridge grating-outcoupled surface-emitting laser incorporating a lateral-grating outcoupler and a first and second lateral-grating distributed Bragg reflector in accordance with the illustrative embodiments;

FIG. 4 depicts a lengthwise sectional view of the lateral-grating grating-outcoupled surface-emitting laser of FIG. 3, in accordance with the illustrative embodiments;

FIGS. 5A and 5B depict top views of other embodiments of lateral-grating distributed Bragg reflectors showing the grating lines on the sidewall region of the lateral-grating distributed Bragg reflector (FIG. 5B), and showing the grating lines of the reflector ending just before the sidewall region (FIG. 5A) of the lateral-grating distributed Bragg reflector;

FIG. 6 shows a top view of another example embodiment of a continuous waveguide ridge grating-outcoupled surface-emitting laser incorporating phase tuning contacts on the first and second lateral-grating distributed Bragg reflectors and a pumped lateral-grating outcoupler, in accordance with the illustrative embodiments;

FIG. 7 is a cross-sectional view of an embodiment of a continuous waveguide ridge grating-outcoupled surface-emitting laser showing phase tuning contacts of the first and second lateral-grating distributed Bragg reflectors and a pumped lateral-grating outcoupler, in accordance with the illustrative embodiments;

FIG. 8 shows another example of the continuous waveguide ridge grating-outcoupled surface-emitting laser of FIG. 7 with phase tuning contacts that are separate, physically from the DBRs, and electrically from the gain region, of the improved laser in accordance with the illustrative embodiments;

FIG. 9 is a widthwise cross-sectional view of an embodiment of a lateral-grating distributed Bragg reflector, formed from semiconductor material in accordance with the illustrative embodiments;

FIG. 10 is a graph indicating the on-resonance field distributions within the grating outcoupler corresponding to the in-phase or maximum radiation, (0 degree phase change) condition, and the 180 degree out-of-phase, no radiation condition;

FIG. 11 shows the calculated relative optical intensity outcoupled from a 15 μm long grating outcoupler as a function of detuning from the Bragg condition as the input phase at one end of the grating is varied, assuming that the field amplitudes are equal at both inputs to the grating;

FIG. 12 is a widthwise cross sectional view of one embodiment of a continuous waveguide ridge grating-outcoupled surface-emitting laser incorporating a loss-coupled lateral-grating distributed Bragg reflector formed from a dielectric and capped with metal, in accordance with the illustrative embodiments;

FIG. 13 is a lengthwise magnified cross-sectional view of a continuous waveguide ridge grating-outcoupled surface-emitting laser incorporating a loss coupled lateral-grating distributed Bragg reflector formed from a dielectric and capped with metal, in accordance with the illustrative embodiments;

FIG. 14 is a flowchart showing a top-level process flow for manufacturing a lateral-grating grating-outcoupled surface-emitting laser in accordance with the illustrative embodiments;

FIG. 15 is a flowchart showing a process flow for one embodiment of a lateral-grating outcoupler and lateral distributed Bragg reflectors, wherein the lines of the grating are formed within a dielectric and capped with metal, in accordance with the illustrative embodiments; and

FIG. 16 is a flowchart showing a process flow for another embodiment of a lateral-grating outcoupler and lateral-grating distributed Bragg reflectors, wherein the grating lines of the components are formed from semiconductor material, in accordance with the illustrative embodiments.

### DETAILED DESCRIPTION OF THE PREFERRED EMBODIMENT

The illustrative embodiments herein are contrasted with traditional grating-outcoupled surface-emitting (GSE) lasers for simplicity and clarity; however, the scope of the illustrative embodiments is not limited by this comparison. The scope of the illustrative embodiments includes edge-emitting lasers. The scope of the illustrative embodiments may also include continuous waveguides that are not waveguide ridges, but continuous waveguides otherwise configured.

A laser is composed of an active laser medium, or gain medium, and a resonant optical cavity. The gain medium transfers external energy into the laser beam. The area of the laser in which this transfer occurs is called the gain region. It is a material of controlled purity, size, concentration, and shape, which amplifies the beam by the quantum mechanical process of stimulated emission. The gain region is pumped, or energized, by an external energy source. Examples of pump sources include electricity and light. The pump energy is absorbed by the laser medium, placing some of its particles into excited quantum states. When the number of particles in one excited state exceeds the number of particles in some lower-energy state, population inversion is achieved. In this condition, an optical beam passing through the gain region produces more stimulated emission than the stimulated absorption, so the beam is amplified. The light generated by stimulated emission is very similar to the input light in terms of wavelength, phase, and polarization. This gives laser light its characteristic coherence, and allows it to maintain the uniform polarization and wavelength established by the optical cavity design.

The optical cavity, an example of a type of cavity resonator, contains a coherent beam of light between reflective surfaces, for example a distributed Bragg reflector, so that each photon passes through the gain region more than once before it is emitted from the output aperture or lost to diffraction or absorption. As light circulates through the cavity, passing through the gain region, if the amplification or gain in the medium is stronger than the resonator losses, the power of the circulating light may rise exponentially. The gain region will amplify any photons passing through it, regardless of direction; but only the photons aligned with the cavity manage to pass more than once through the medium and so have significant amplification.

Semiconductor lasers within the scope of the illustrative embodiments may be based upon one of four different types of materials, depending upon the wavelength region of interest. Three of the materials are III-V semiconductors, consisting of materials in columns III and V of the periodic table. Examples of column III atoms include aluminum (Al), gallium (Ga), indium (In), and thallium (Tl), and examples of column V atoms are nitrogen (N), phosphorus (P), arsenic (As), and antimony (Sb). Semiconductor lasers in the near infrared and extending into the visible may be based on GaAs/AlGaAs layers. Indium phosphide (InP) may be used to produce lasers in the 1.5 μm wavelength region with InP/InGaAaP layered materials. Gallium nitride (GaN) may be used for blue and ultraviolet lasers.

Other materials within the scope of the illustrative embodiments are based on II-VI compounds, consisting of materials in columns II and VI of the periodic table. Examples of column II atoms are zinc (Zn) and cadmium (Cd). Examples of column VI atoms are sulfur (S), selenium (Se), and tellurium (Te). An example II-VI compound is zinc selenide (ZnSe), which may be used for blue-green lasers. Many more compounds may be used for semiconductor lasers, producing lasers of various wavelengths, and all of them are within the scope of the present invention.

Traditional grating-outcoupled surface-emitting (GSE) lasers typically have a primary waveguide ridge that is limited to the gain region of the laser. If there is no lateral confinement in the outcoupler or distributed Bragg reflectors regions, the light diffracts and the efficiency of the distributed Bragg reflectors and outcoupler is reduced as the light energy leaves the waveguide ridge to enter the outcoupler and distributed Bragg reflectors. In traditional GSE lasers, the efficiencies of the outcoupler and distributed Bragg reflectors may be increased by fabricating a secondary waveguide to laterally confine the light in accordance with the illustrative embodiments. Such a secondary waveguide adds to the complexity of fabrication in that the secondary waveguide process is typically in addition to forming the waveguide ridge for the active gain regions. Although the lateral losses are reduced, the losses are not completely eliminated.

In addition to these lateral losses, in traditional grating-outcoupled surface-emitting lasers, there are also vertical losses. Vertical losses occur because of the difference in the vertical optical field distribution under the primary waveguide ridge and the vertical optical field distribution in the distributed Bragg reflector or outcoupling region. In traditional grating-outcoupled surface-emitting lasers this difference in the vertical optical field distribution is due to the discontinuity between the primary waveguide ridge and the grating regions. These waveguide discontinuities in traditional grating-outcoupled surface-emitting lasers cause scattering losses.

The illustrated embodiments provide a system and a method of manufacture for a lateral-grating grating-outcoupled surface-emitting laser. The illustrative embodiments provide an improved laser comprising a continuous waveguide ridge extending the length of the laser. Therefore, other components, for example, outcoupling gratings and distributed Bragg reflectors, within the laser may be formed with the continuous waveguide ridge situated centrally along the entire device. As a result of this configuration, the lateral and vertical losses of the traditional grating-outcoupled surface-emitting laser may be eliminated.

One embodiment of a lateral-grating grating-outcoupled surface-emitting laser illustrated in the detailed description depicts a single gain region laser. However, it should be noted that many configurations of a continuous waveguide ridge lateral-grating grating-outcoupled surface-emitting laser are possible within the scope of the illustrative embodiments. For example, the outcoupler region may be located centrally on the laser device between two active gain regions. Further, in one illustrative embodiment, a lateral-grating outcoupler and a pair of lateral-grating distributed Bragg reflectors are formed with the continuous waveguide ridge interrupting the grating lines of the lateral-grating outcoupler and the grating lines of the lateral-grating distributed Bragg reflectors. The grating lines are formed substantially perpendicular and through the center of each of the components. In another illustrative embodiment, the lateral-grating outcoupling grating and lateral-grating distributed Bragg reflectors are formed with a plurality of grating lines extending continuously across the continuous waveguide ridge.

One of the advantages of a continuous waveguide ridge grating-outcoupled surface-emitting laser, as compared to a traditional grating-outcoupled surface-emitting laser, is the ability to reduce the light scattering losses to a negligible amount at component transitions. In other words, the continuous waveguide ridge extending through the lateral outcoupler and lateral distributed Bragg reflector provides a method to eliminate optical losses at waveguide transitions between gain regions, outcouplers, and distributed Bragg reflectors. Another advantage of a lateral-grating GSE laser is there are no residual reflections at transitions. Yet another advantage of a lateral-grating GSE laser is the additional increased efficiency in laser coupling to another monolithically integrated component.

The continuous waveguide ridge of the lateral-grating GSE laser may be further improved by fabricating loss-coupled lateral-gratings capping a dielectric used to form the grating lines with a metal. Using a metal over the distributed Bragg reflector grating, forces the field to remain in the low-loss regions between the metal-containing grooves, and therefore, the phase of the optical field is stabilized as compared to other edge-emitting and surface-emitting semiconductor lasers with index-coupled gratings formed from semiconductor material.

In edge-emitting index-coupled distributed Bragg reflector lasers, the magnitude of the reflectivity of the distributed Bragg reflectors depends on the exact location of the terminating facet with respect to the grating. The phase stabilization due to loss coupled distributed Bragg reflectors is important because the optical field intensity peaks are locked to the low loss regions of the grating. Therefore, loss-coupled distributed Bragg reflectors increase the yield of edge-emitting distributed Bragg reflector lasers.

The outcoupler grating in a GSE laser is sensitive to the input phases of the optical fields incident on the outcoupler grating. Stabilizing the phase of the optical fields with loss-coupled distributed Bragg reflectors forces stable operation of the outcoupling grating.

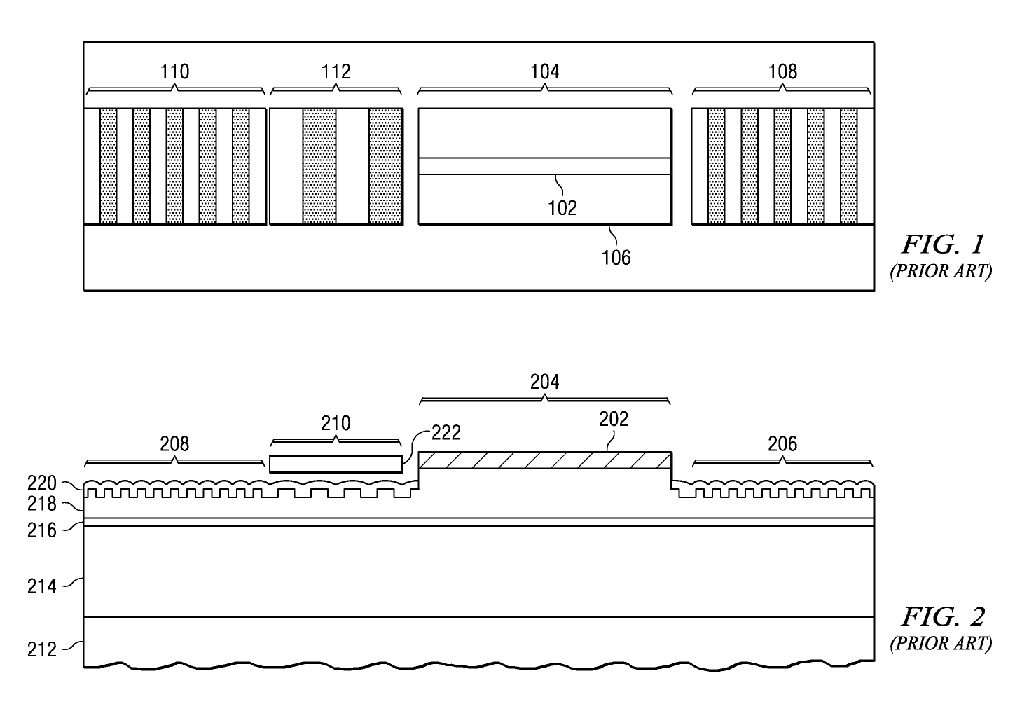

With reference now to the figures and in particular with reference to FIG. 1, a top view of a known grating-outcoupled surface-emitting laser is shown. As can be seen from FIG. 1, waveguide ridge 102 extends the length of gain region 104. Gain region 104 has metal contact layer 106 covering waveguide ridge 102. Distributed Bragg reflectors 108 and 110 are shown on both ends of the grating-outcoupled surface-emitting laser. Outcoupler 112 is shown adjacent to gain region 104. Grating lines in distributed Bragg reflectors 108 and 110, as well as outcoupler 112, are indicative of the height variation within outcoupler 112 and distributed Bragg reflectors 108 and 110.

FIG. 2 depicts a lengthwise cross-sectional view of the known grating-outcoupled surface-emitting laser of FIG. 1. The cross-section of the grating-outcoupled surface-emitting laser is in the direction of the length of the waveguide ridge. Metal contact 202 is shown over the gain region of waveguide ridge 204.

The traditional grating-outcoupled surface-emitting laser illustrated in FIG. 2 is formed on gallium arsenide (GaAs) substrate 212. Epitaxial layers consisting of aluminum gallium arsenide (AlGaAs) 214, indium gallium arsenide (InGaAs) forming the quantum well 216, another layer of aluminum gallium arsenide (AlGaAs) 218, and gallium arsenide (GaAs) 220 are formed on gallium arsenide (GaAs) substrate 212.

The relatively thin layer of indium gallium arsenide (InGaAs) 216 is termed the quantum well. A quantum well is a potential well that confines carriers, which were originally free to move in three dimensions, to two dimensions, forcing them to occupy a planar region. The effects of quantum confinement take place when the quantum well thickness becomes comparable at the de Broglie wavelength of the carriers, generally electrons and holes. The quantum well may be grown by molecular beam epitaxy or vapor deposition by controlling the layer thickness down to monolayers.

Distributed Bragg reflectors 206 and 208 and outcoupler 210 have no primary waveguide ridge 204. Waveguide ridge 204 is not continuous through the length of the traditional grating-outcoupled surface-emitting (GSE) laser.

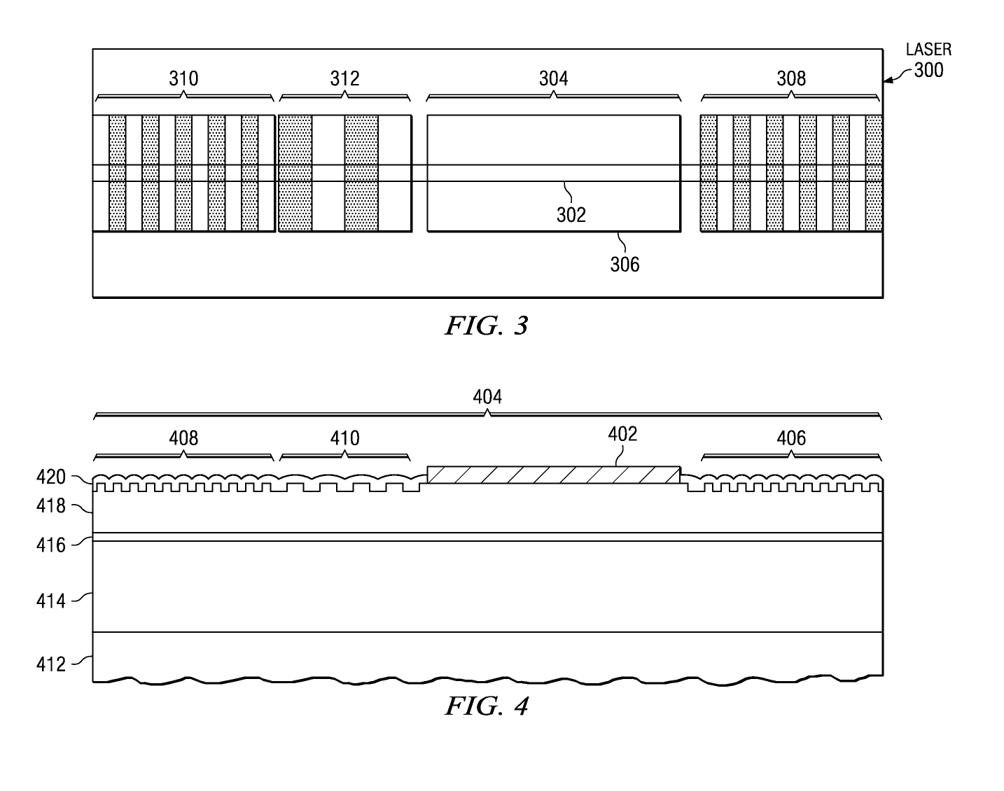

FIG. 3 is a top view of a continuous waveguide ridge lateral-grating GSE laser incorporating a lateral-grating outcoupler and a first and second lateral-grating distributed Bragg reflector in accordance with the illustrative embodiments. A lateral-grating distributed Bragg reflector is a distributed Bragg reflector with the waveguide ridge extending through the center region of the distributed Bragg reflector.

As can be seen from FIG. 3, waveguide ridge 302 is continuous and extends the length of the GSE laser. Waveguide ridge 302 extends through gain region 304, shown with gain contact 306, lateral-grating distributed Bragg reflectors 308 and 310, and through lateral-grating outcoupler 312. A lateral-grating distributed Bragg reflector is formed on either side of waveguide ridge 302. The grating lines of lateral-grating distributed Bragg reflector 308 and 310 are formed substantially perpendicular to waveguide ridge 302. In the embodiment depicted, the grating lines are formed over waveguide ridge 302.

Note that lateral-grating outcoupler 312 of the GSE laser is similar in structure to lateral-grating distributed Bragg reflectors 308 and 310, with the exception that the period of grating lines in lateral-grating outcoupler 312 may be greater than the period of the grating lines in lateral-grating distributed Bragg reflectors 308 and 310. All of the illustrative embodiments attributed to a lateral distributed Bragg reflector may also be applicable to a lateral outcoupler.

FIG. 4 depicts a lengthwise sectional view of the lateral-grating grating-outcoupled surface-emitting laser of FIG. 3 in accordance with the illustrative embodiments. In other words, FIG. 4 is a section of the continuous waveguide ridge of FIG. 3 cut lengthwise the extent of the GSE laser. A metal contact is shown over gain region 402 of continuous waveguide ridge 404. Lateral-grating distributed Bragg reflector 406 and lateral-grating distributed Bragg reflector 408 are shown formed on top of continuous waveguide ridge 404. Lateral-grating outcoupler 410 is also shown formed on top of continuous waveguide ridge 404. While the grating lines in this embodiment cross over continuous waveguide ridge 404 due to an artifact of manufacturing, this embodiment is useful in illustrating continuous waveguide ridge 404 through gain region 402, lateral-grating distributed Bragg reflectors 406 and 408, respectively, and lateral-grating outcoupler 410. Continuous waveguide ridge 404 is continuous through the length the lateral-grating GSE laser.

The lateral-grating GSE laser illustrated in FIG. 4 may comprise the same layers as the traditional GSE laser illustrated in FIG. 2. The lateral-grating GSE laser is formed on gallium arsenide (GaAs) substrate 412. Epitaxial layers consisting of aluminum gallium arsenide (AlGaAs) 414, indium gallium arsenide (InGaAs) forming quantum well 416, another layer of aluminum gallium arsenide (AlGaAs) 418, and another layer of gallium arsenide (GaAs) 420 are formed on gallium arsenide (GaAs) substrate 412.

In this example of the illustrative embodiments, distributed Bragg reflectors 406 and 408 and outcoupler 410 are formed in aluminum gallium arsenide (AlGaAs) layer 418 and capped in gallium arsenide (GaAs) 420.

In other illustrative embodiments, the distributed Bragg reflectors and outcoupler may be formed from a dielectric, such as a silicon nitrite or silicon dioxide layer. All of the structural variations of the lateral-grating distributed Bragg reflector in the illustrative embodiments may also be implemented on the lateral-grating outcoupler.

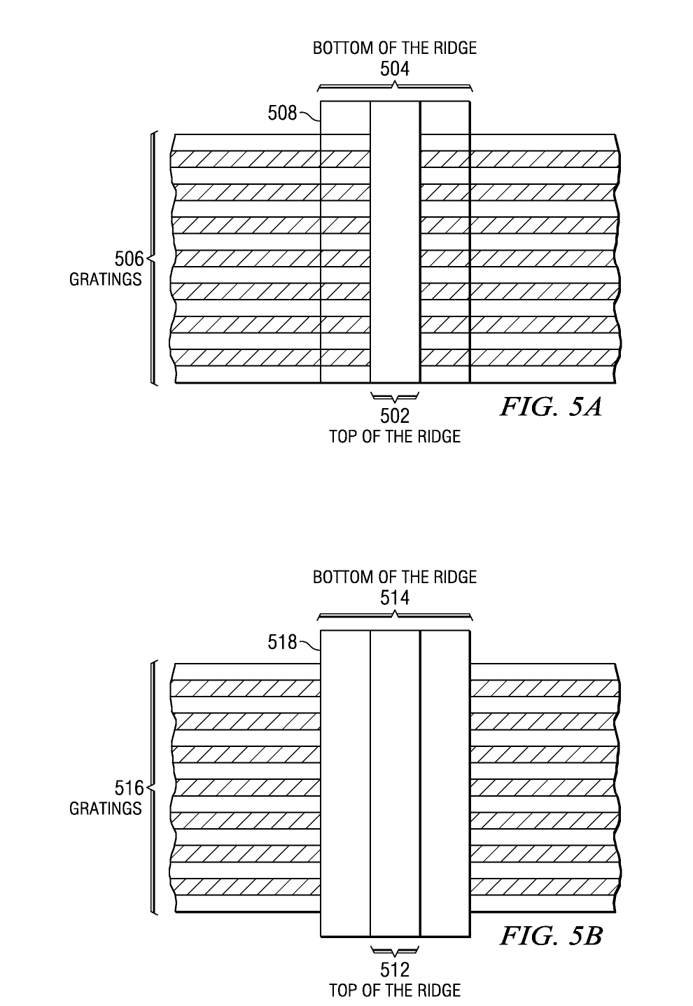

FIGS. 5A and 5B are top views of other embodiments of a lateral-grating distributed Bragg reflectors, in accordance with the illustrative embodiments. FIG. 5A shows top of continuous waveguide ridge 502 and bottom of continuous waveguide ridge 504, indicating there is a slope to the sidewall of the continuous waveguide ridge. Lateral-grating distributed Bragg reflector lines 506 extend upward from the bottom of continuous waveguide ridge 504 and end before reaching the top of continuous waveguide ridge 502. Region 508 of the grating lines indicates the sidewall of top of continuous waveguide ridge 502.

FIG. 5B is yet another embodiment of a lateral-grating distributed Bragg reflector in accordance with the illustrative embodiments. Top of continuous waveguide ridge 512 and bottom of continuous waveguide ridge 514 are indicated. Lateral-grating distributed Bragg reflector lines 516 are shown ending at bottom of continuous waveguide ridge 514. Continuous waveguide ridge sidewall region 518 has no grating lines. The scope of the illustrative embodiments includes distributed Bragg reflectors and outcouplers that have grating lines that end before the continuous waveguide ridge sidewall, anywhere within the continuous waveguide ridge sidewall, or grating lines that are continuous across the top of the continuous waveguide ridge.

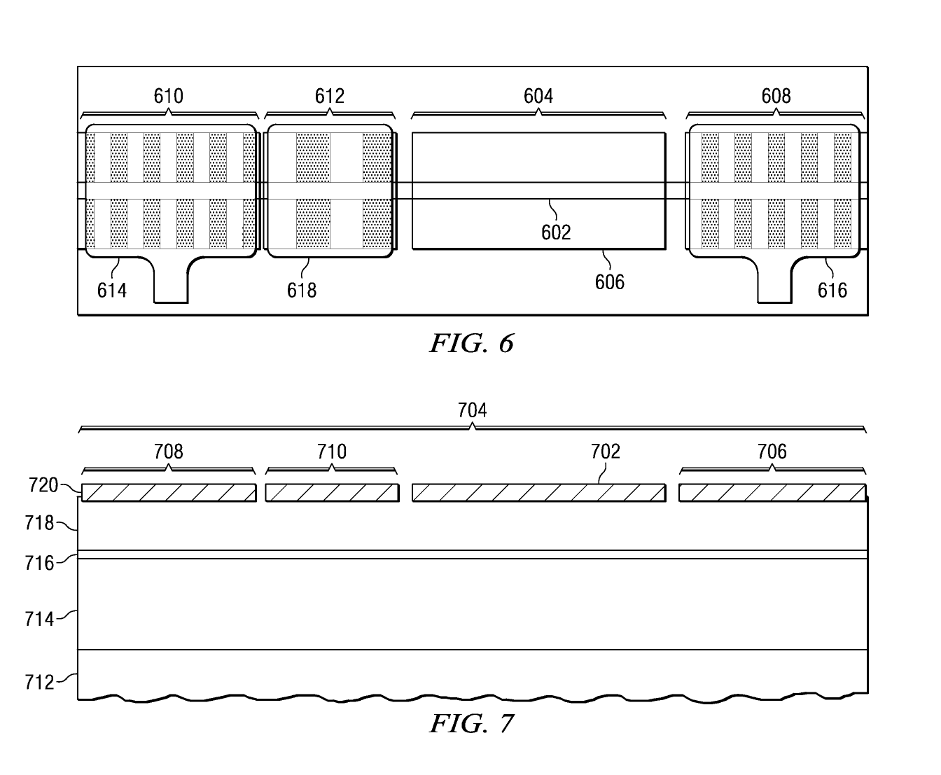

FIG. 6 is a top view of another embodiment of a lateral-grating grating-outcoupled surface-emitting laser showing phase tuning contacts on the first and second lateral distributed Bragg reflectors and an outcoupler mirror, in accordance with the illustrative embodiments. Continuous waveguide ridge 602 extends the length of the laser. Continuous waveguide ridge 602 extends through gain region 604, shown with gain contact 606, lateral distributed Bragg reflectors 608 and 610, and through lateral outcoupler 612 as in FIG. 3. In addition, however, are phase tuning contacts 614 and 616. Lateral distributed Bragg reflectors 608 and 610 may be tuned by pumping the reflectors using electrical current injection. By applying a controlled amount of electrical current to the distributed Bragg reflector, the phase tuning contacts and gain regions within the lateral distributed Bragg reflector may be controlled. In addition, a section of the gain region may be electrically isolated and used as a pure phase controller.

Pumped lateral-grating outcoupler 618 may be included in the laser with or without phase tuning contacts 614 and 616 of distributed Bragg reflectors 608 and 610.

FIG. 7 is a cross sectional view of an embodiment of a lateral-grating grating-outcoupled surface-emitting laser showing phase tuning contacts of the first and second lateral distributed Bragg reflectors and outcoupler mirror, in accordance with the illustrative embodiments. FIG. 7 is the cross sectional view of the embodiment of FIG. 6. Active gain region 702, continuous waveguide ridge 704, lateral-grating distributed Bragg reflectors 706 and 708, and lateral-grating outcoupler 710 are depicted. The lateral-grating GSE laser is formed on gallium arsenide (GaAs) substrate 712. Epitaxial layers consisting of aluminum gallium arsenide (AlGaAs) 714, indium gallium arsenide (InGaAs) forming quantum well 716, and another layer of aluminum gallium arsenide (AlGaAs) 718 are formed on gallium arsenide (GaAs) substrate 712. In this cross-section, continuous waveguide ridge 704, such as waveguide ridge 602 of FIG. 6, does not have the grating lines from lateral-grating outcoupler 710 or distributed Bragg reflectors 706 and 708 formed on top. The grating lines may not be formed or the grating lines may be etched off the top of continuous waveguide ridge 704. Metal contact layer 720 is depicted.

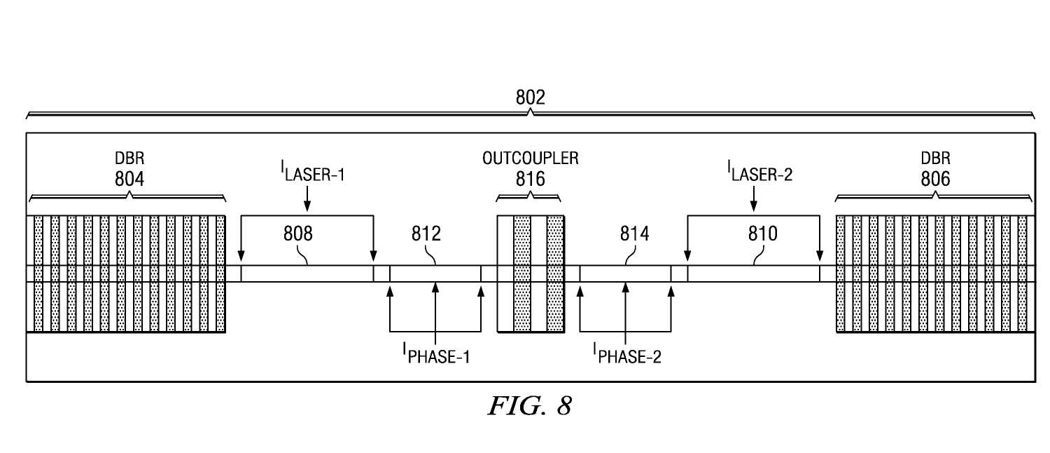

FIG. 8 shows another example of the continuous waveguide ridge GSE laser with phase tuning contacts that may be separate physically from the distributed Bragg reflectors, and electrically from the gain region of the GSE laser in accordance with the illustrative embodiments. Waveguide ridge 802 extends continuously the length of the GSE laser. FIG. 8 shows an example of a more complex GSE laser in accordance with the illustrative embodiments. The laser has two lateral-grating distributed Bragg reflectors 804 and 806 on either end of the laser. Two active gain regions 808 and 810 are also shown, as well as two physically and electrically separate phase controllers 812 and 814. Outcoupler 816 is located centrally on the laser.

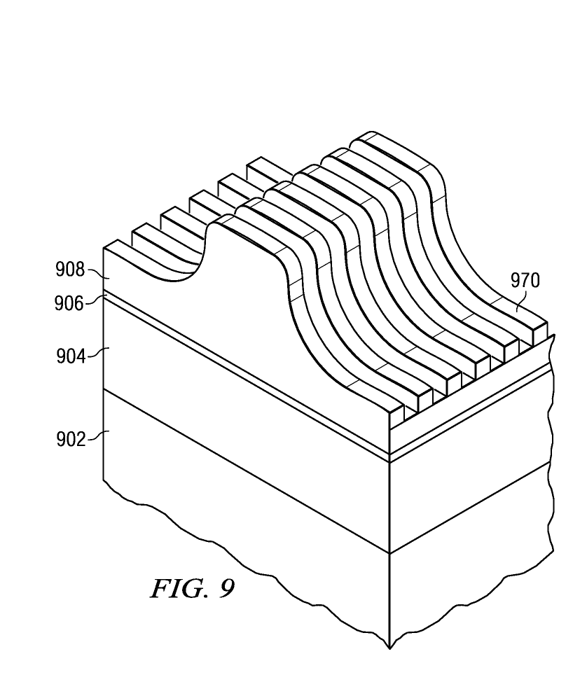

FIG. 9 is a widthwise-sectional view of another embodiment of a lateral-grating distributed Bragg reflector, formed from semiconductor material, as shown in FIG. 3, in accordance with the illustrative embodiments. The layers shown are gallium arsenide (GaAs) substrate 902, epitaxial layers consisting of aluminum gallium arsenide (AlGaAs) 904, indium gallium arsenide (InGaAs) forming quantum well 906, and aluminum gallium arsenide (AlGaAs) 908. However, the topmost layer depicted in FIG. 9 may be a gallium arsenide (GaAs) cap, and thus the distributed Bragg reflectors and outcoupler are formed from the semiconductor materials aluminum gallium arsenide (AlGaAs) and gallium arsenide (GaAs).

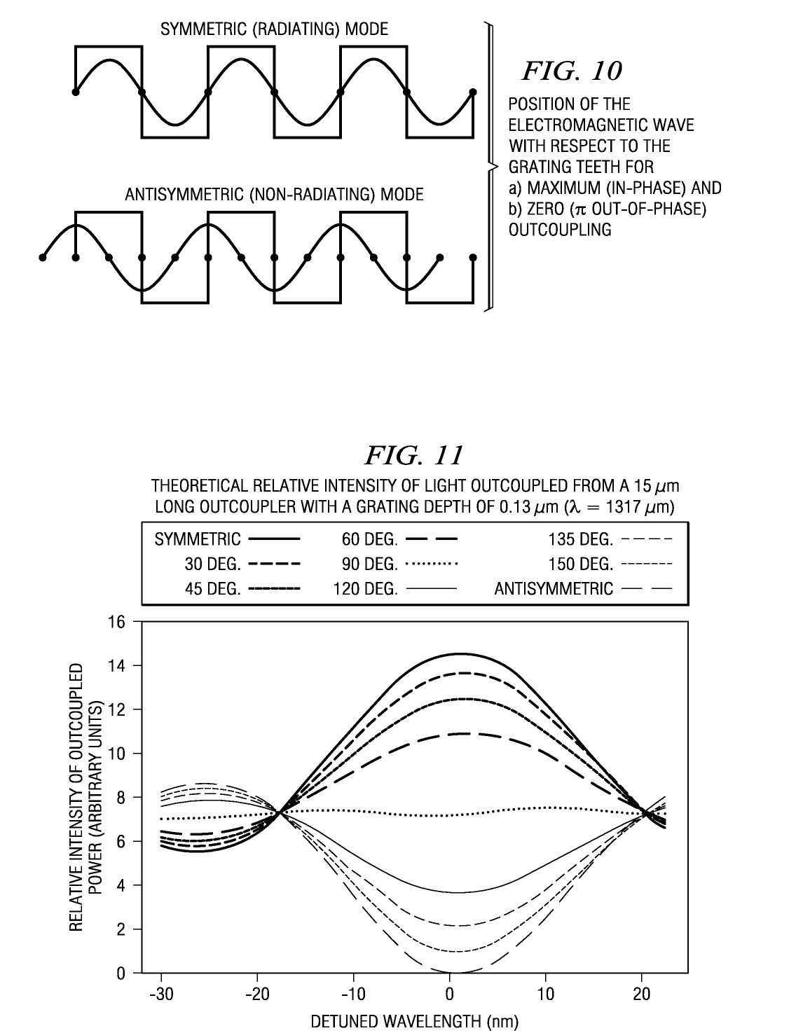

In operating a laser in which the grating lines of the distributed Bragg reflectors are formed to provide loss-free index coupling, it may be difficult to provide stability in the relative intensity of the grating-outcoupled power and/or stability in the near-field and far-field shape and intensity, as shown in FIGS. 10 and 11 below. Near-field and far-field refers to the size and intensity of a laser spot close to the source of light generation (near-field), and at a distance far from the source of light generation (far-field).

FIGS. 10 and 11 are included herein to emphasize the difficulties in providing a stabilized optical intensity output, while providing near-field and far-field stability in a loss-free index guided semiconductor laser.

FIG. 10 is a graph indicating the on-resonance field distributions within the grating outcoupler corresponding to the in-phase or maximum radiation, 0 degree phase change, and 180 degree out-of-phase, no radiation condition.

FIG. 11 shows calculated values for the relative optical intensity outcoupled from a grating outcoupler as a function of detuning from the Bragg condition, as the input phase at one end of the grating outcoupler is varied. The relative optical intensity outcoupled plot indicates that if the grating period of a 15 micron long outcoupler is detuned by approximately 20 nm, the outcoupled intensity is insensitive to phase variations. However, if the outcoupler is on-resonance, the output beam may vary from a maximum value to zero depending on the phase value. The near-field and far-fields corresponding to the on-resonance condition are always stable; however, the outcoupled power varies with phase changes. Although appropriate detuning provides a constant output power (“phase insensitive outcoupling”), the near-field and far-field intensity patterns in this case change with phase, which is also undesirable in many applications. The on-resonance near-field distributions within the grating outcoupler corresponding to the in-phase, maximum radiation (0 degree phase change), and the 180 degree out-of-phase, no radiation conditions are shown in FIG. 10.

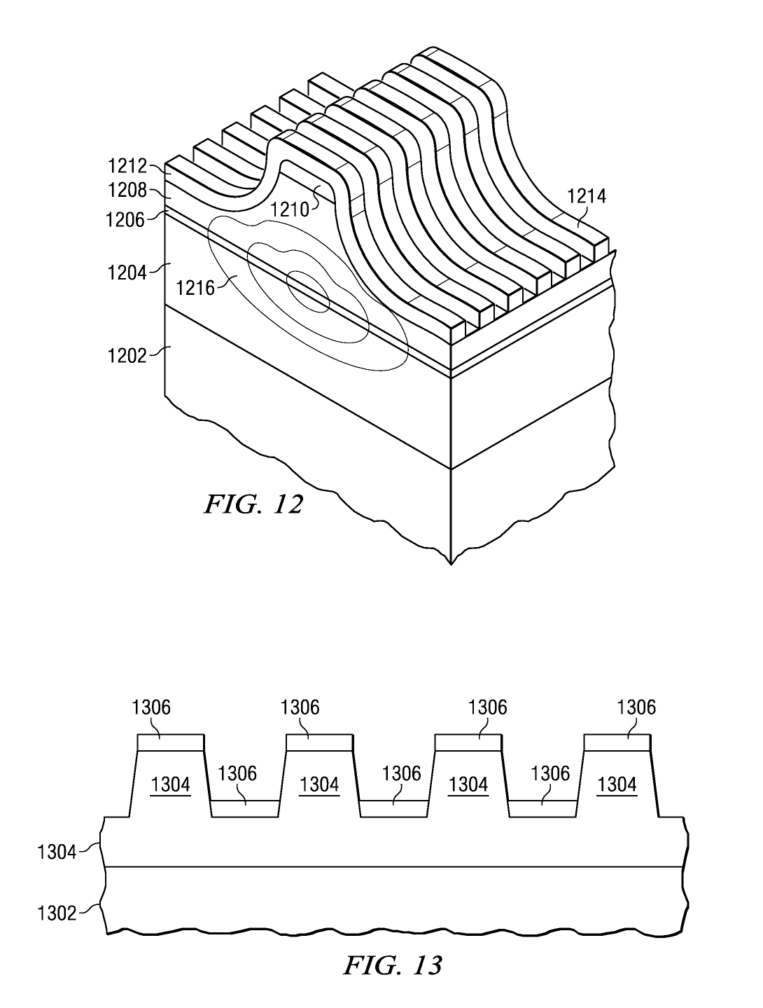

FIG. 12 is a widthwise sectional view of one embodiment of a loss-coupled lateral-grating distributed Bragg reflector formed from a dielectric capped with metal in accordance with the illustrative embodiments. The dielectric may be, for example, silicon nitrite or silicon dioxide.

The pictured embodiment of a loss-coupled lateral-grating outcoupler is formed wherein each grating line of the outcoupler is continuous from the left side of the outcoupler over the waveguide ridge to the right side of the outcoupler. The layers forming the sub structure are the same as the lateral-grating distributed Bragg reflector layers in FIG. 4, namely gallium arsenide (GaAs) substrate 1202, epitaxial layers consisting of aluminum gallium arsenide (AlGaAs) 1204, and 1208, indium gallium arsenide (InGaAs) forming quantum well 1206, and gallium arsenide (GaAs) cap 1210. However, the topmost two layers depicted in FIG. 12 are Si₃N₄ layer 1212 and metal layer 1214. The grating lines for the loss-coupled lateral-grating outcoupler are formed in a dielectric such as silicon nitride (Si₃N₄) or silicon Oxide (SiO₂), and capped with metal.

Feature 1216 is sketched onto FIG. 12 to illustrate the light intensity distribution in the cross section of the waveguide ridge. The probability of highest intensity light is shown in the center of feature 1216. The loss-coupled grating used on resonance forces the optical fields to operate in the maximum outcoupling condition for all phase values. Therefore, in accordance with the illustrative embodiments, incorporating loss-coupled lateral-grating outcoupled gratings with loss-coupled lateral-grating distributed Bragg reflectors with a continuous waveguide ridge further increases GSE laser yield.

FIG. 13 is a further magnified cross-sectional view of a loss-coupled lateral-grating distributed Bragg reflector formed from silicon nitrite and capped with metal, in accordance with the illustrative embodiments. Layer 1302 may be comprised of gallium arsenide (GaAs) or aluminum gallium arsenide (AlGaAs). Layer 1304 may be comprised of silicon nitride (Si₃N₄), and layer 1306 may be comprised of metal. The thickness of Si₃N₄ layer 1304 may be zero on lower grating line features 1304. Metal layer 1306 may be discontinuous as shown in FIG. 13 or may be a conformal layer of metal.

By fabricating loss-coupled lateral-grating GSE lasers using a metal cap over the distributed Bragg reflector grating, the field is forced to remain in the low-loss regions between the metal grooves, and therefore, the phase of the optical field is stabilized as compared to other edge- and surface-emitting semiconductor lasers with pure index-coupled gratings. In edge-emitting index-coupled distributed Bragg reflector lasers, the magnitude of the reflectivity of the distributed Bragg reflector depends on the exact location of the terminating facet with respect to the grating. The phase stabilization due to loss coupled distributed Bragg reflectors is important because the optical field intensity peaks are locked to the low-loss regions of the grating. Therefore, loss-coupled distributed Bragg reflectors increase the yield of edge-emitting distributed Bragg reflector lasers as well as GSE lasers.

The outcoupler grating in GSE lasers is sensitive to the input phases of the optical fields incident on the outcoupler grating. Stabilizing the optical fields with a loss-coupled outcoupling grating forces the outcoupling grating to operate at maximum outcoupling efficiency, since the optical field peaks are aligned with the grating peaks.

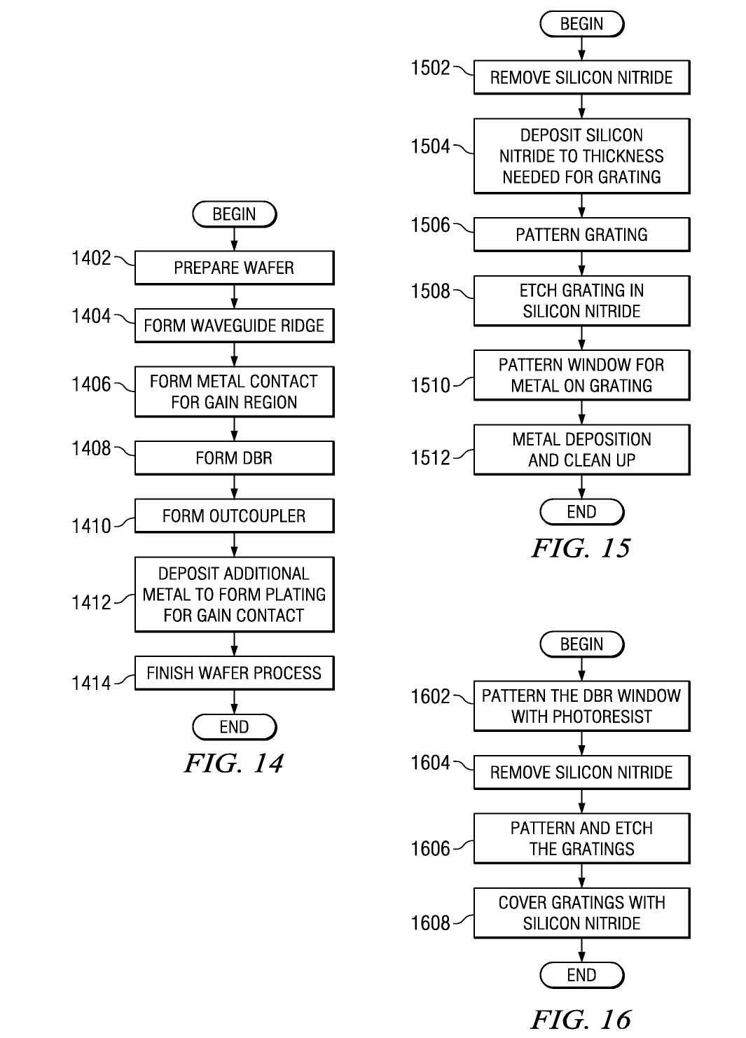

FIG. 14 is a flowchart showing a top-level process flow for manufacturing a lateral-grating GSE laser in accordance with the illustrative embodiments. To begin the process, the semiconductor wafer is prepared (step 1402) using methods well understood by those of ordinary skill in the art.

The continuous waveguide ridge process (step 1404) begins by protecting the continuous waveguide ridge with a photoresist pattern. The semiconductor wafer is then etched. The areas of the laser that are not a part of the continuous waveguide ridge, and are therefore not protected by photoresist are etched out.

Next, a layer of silicon nitride is deposited on the wafer. With the photoresist remaining on the continuous waveguide ridge, silicon nitride (Si₃N₄) is deposited on the semiconductor wafer. The photoresist is then lifted off the continuous waveguide ridge structure in a removal process, leaving the continuous waveguide ridge area free from silicon nitride and a layer of silicon nitride elsewhere on the semiconductor wafer. Thus, a continuous waveguide ridge is defined on the laser structure, completing step 1404. Other processes within the scope of the illustrative embodiments may be defined for forming the continuous waveguide ridge.

Next, the metal contact for the gain region of the continuous waveguide ridge is formed (step 1406). First, a layer of photoresist coats the negative contact pattern of the gain contact. The metal is then deposited. An example of p-type contact metal is TiPtAu, and NiAuGe is an example of n-type contact metal. Finally, the metal deposited over the photoresist and the photoresist protecting the non-contact regions of the structure are lifted off, leaving a metal contact region on the continuous waveguide ridge, thus forming the gain region of the laser. Lasers with multiple gain regions are within the scope of the illustrative embodiments as well as other configurations of laser, such as locating the grating outcoupler outside of the gain and distributed Bragg reflector regions.

There are multiple embodiments for forming the distributed Bragg reflector (step 1408) and the outcoupler (step 1410) regions. If the grating line process is implemented using holographic methods, the distributed Bragg reflectors and the outcoupler regions may be processed in separate steps. If however, an e-beam process is used, the distributed Bragg reflectors and the outcoupler regions may be processed in the same step. Two example embodiments of distributed Bragg reflectors and outcouplers are discussed further in FIGS. 15 and 16. However, the illustrative embodiments are not intended to be limited by these embodiments. Rather the embodiments are meant as examples of the variations within the scope of the illustrative embodiments.

Following the formation of the lateral outcoupler and lateral distributed Bragg reflectors (steps 1408 and 1410), the plating for the gain contact is patterned, and a second layer of metal is deposited to form the plating for the gain contact (step 1412). The wafer is then finished in a series of finishing steps well known in the laser processing art (step 1414).

FIG. 15 is a flowchart showing a process flow for one embodiment of a lateral-grating outcoupler and lateral distributed Bragg reflectors, wherein the lines of the grating are formed from silicon nitrite and capped with metal, in accordance with the illustrative embodiments. FIG. 15 is a top-level process flowchart for one embodiment of the lateral outcoupler and lateral distributed Bragg reflectors of FIG. 3. FIG. 15 provides further detail of the illustrative embodiment of steps 1408 and 1410 of FIG. 14.

The process begins by removing the silicon nitride in an etch process (step 1502). Next, the silicon nitride is re-deposited to the thickness needed for the formation of the gratings (step 1504). The grating is then patterned (step 1506). As discussed above, this may be two patterning steps, one for the distributed Bragg reflector gratings and another for the outcoupler, if a holographic patterning process is used. Photolithographic techniques allow diffraction gratings to be created from a holographic interference pattern. Semiconductor etch technology is used to etch holographically patterned wafers. In this way, holography is incorporated into high volume, low cost semiconductor manufacturing technology. On the other hand, if an e-beam process is used, these steps may be incorporated into one patterning step. Both processes holographic and e-beam are within the scope of the illustrative embodiments.

Next, the gratings are etched into the silicon nitride (step 1508). The next step comprises opening a negative pattern for the metal cap on the distributed Bragg reflectors (1510). The metal is then deposited and the photoresist and metal deposited on the non-gratings is lifted off (step 1512), thus forming a loss-coupled lateral-grating outcoupler and loss-coupled lateral-grating distributed Bragg reflectors from silicon nitride with a metal cap, and thereby ending the process.

FIG. 16 is a flowchart showing a process flow for another embodiment of a lateral-grating outcoupler and lateral distributed Bragg reflectors, wherein the grating lines of the components are formed from semiconductor material, in accordance with the illustrative embodiments. FIG. 16 provides further detail of the illustrative embodiment of steps 1408 and 1410 of FIG. 14.

The process begins by providing a negative pattern window for the distributed Bragg reflectors and outcoupler (step 1602). The silicon nitride is then removed from the distributed Bragg reflectors and outcoupler windows (step 1604). Next, the distributed Bragg reflectors and outcouplers are patterned and etched (step 1606). As discussed above, the patterning step for the distributed Bragg reflectors and the outcouplers may be two steps if patterned holographically, or one step if patterned with an e-beam process. The pattern is then etched (step 1606). Finally, silicon nitride is deposited on the gratings (step 1608).

The description of the illustrative embodiments of the present invention has been presented for purposes of illustration and description, but is not intended to be exhaustive or limited to the invention in the form disclosed. Many modifications and variations will be apparent to those of ordinary skill in the art. The embodiment was chosen and described in order to best explain the principles of the invention and the practical application to enable others of ordinary skill in the art to understand the invention for various embodiments with various modifications as are suited to the particular use contemplated.

What is claimed is:

1. An index guided semiconductor laser comprising:
a gain region;
a continuous waveguide; and
at least one lateral-grating distributed Bragg reflector or a lateral-grating outcoupler, wherein the continuous waveguide extends through the gain region and the at least one lateral-grating distributed Bragg reflector or the lateral-grating outcoupler.

2. The index guided semiconductor laser of claim 1, wherein the continuous waveguide is a continuous waveguide ridge.

3. The index guided semiconductor laser of claim 1, wherein the index guided semiconductor laser is a grating-outcoupled surface-emitting laser.

4. The index guided semiconductor laser of claim 1, wherein the index guided semiconductor laser is an edge-emitting laser, and wherein the continuous waveguide extends through the gain region and the at least one lateral distributed Bragg reflector.

5. The index guided semiconductor laser of claim 1, wherein the lateral-grating outcoupler further comprises:
a first plurality of grating lines and a second plurality of grating lines, wherein the first plurality of grating lines and the second plurality of grating lines are positioned substantially perpendicular to the continuous waveguide, with the first plurality of grating lines on a first side of the continuous waveguide and the second plurality of grating lines on a second side of the continuous waveguide.

6. The index guided semiconductor laser of claim 1, wherein the at least one lateral-grating distributed Bragg reflector further comprises:
a first plurality of grating lines and a second plurality of grating lines, wherein the first plurality of grating lines and the second plurality of grating lines are positioned substantially perpendicular to the continuous waveguide, with the first plurality of grating lines on a first side of the continuous waveguide and the second plurality of grating lines on a second side of the continuous waveguide.

7. The index guided semiconductor laser of claim 1, wherein the lateral-grating outcoupler further comprises:
a plurality of grating lines extending continuously across the continuous waveguide substantially perpendicular to the continuous waveguide.

8. The index guided semiconductor laser of claim 1, wherein the at least one lateral-grating distributed Bragg reflector further comprises:
a plurality of grating lines extending across the continuous waveguide substantially perpendicular to the continuous waveguide.

9. The index guided semiconductor laser of claim 1, wherein a phase controller is incorporated into the at least one lateral-grating distributed Bragg reflector.

10. The index guided semiconductor laser of claim 1, wherein a phase controller is physically separated from the at least one lateral-grating distributed Bragg reflector and electrically separate from an active gain region.

11. The index guided semiconductor laser of claim 1, wherein a pumping contact is incorporated into the lateral-grating outcoupler.

12. An index guided semiconductor laser comprising:
a gain region; and
at least one distributed Bragg reflector, wherein a plurality of grating lines of the at least one distributed Bragg reflector are processed from a dielectric and capped with a metal, forming a loss-coupled distributed Bragg reflector.

13. The index guided semiconductor laser of claim 12, wherein the loss-coupled distributed Bragg reflector is a loss-coupled lateral-grating distributed Bragg reflector.

14. An index guided semiconductor laser comprising:
a gain region; and
at least one outcoupler, wherein a plurality of grating lines of the at least one outcoupler are processed from a dielectric and capped with a metal, forming a loss-coupled outcoupler.

15. The index guided semiconductor laser of claim 14, wherein the loss-coupled outcoupler is a loss-coupled lateral-grating outcoupler.

16. An index guided semiconductor laser comprising:
at least one gain region;
at least one loss-coupled lateral-grating distributed Bragg reflector;
at least one loss-coupled lateral-grating outcoupler; and
a continuous waveguide, wherein the continuous waveguide ridge extends through the at least one gain region, the at least one loss-coupled lateral-grating distributed Bragg reflector, and the at least one loss-coupled lateral-grating outcoupler.

17. The index guided semiconductor laser of claim 16, wherein the at least one loss-coupled lateral-grating distributed Bragg reflector has a contact to enable phase control.

18. A method of manufacture for an index guided semiconductor laser comprising:
preparing a semiconductor wafer;
forming a continuous waveguide;
forming metal contact for a gain region;
forming lateral distributed Bragg reflectors;
forming lateral outcoupler gratings; and
finishing a semiconductor wafer process.

19. The method of manufacture for the index guided semiconductor laser of claim 18, wherein the continuous waveguide is a continuous waveguide ridge.

20. The method of manufacture for the index guided semiconductor laser of claim 18, wherein the index guided semiconductor laser is a grating-outcoupled surface-emitting laser.

21. The method of manufacture for the index guided semiconductor laser of claim 18, wherein the index guided semiconductor laser is an edge-emitting laser.

22. The method of manufacture for the index guided semiconductor laser of claim 18, wherein the index guided semiconductor laser has multiple gain regions.

23. The method of manufacture for the index guided semiconductor laser of claim 18, wherein the index guided semiconductor laser has multiple outcoupler gratings.

24. The method of manufacture for the index guided semiconductor laser of claim 18, wherein the index guided semiconductor laser has a plurality of phase controllers.

25. The method of manufacture for the index guided semiconductor laser of claim 18, further comprising:
forming a contact for a loss-coupled lateral-grating distributed Bragg reflector to enable phase control.
